(19) United States
(12) Patent Application Publication
(10) Pub. No.: US 2026/0113942 A1
(43) Pub. Date: Apr. 23, 2026

(54) THREE-DIMENSIONAL SEMICONDUCTOR MEMORY DEVICE AND ELECTRONIC SYSTEM INCLUDING THE SAME

(71) Applicant: Samsung Electronics Co., Ltd., Suwon-si (KR)

(72) Inventors: Suhwan LIM, Suwon-si (KR); Junyeong LIM, Suwon-si (KR); KWANG-SOO KIM, Suwon-si (KR); Wanki KIM, Suwon-si (KR)

(21) Appl. No.: 19/217,280

(22) Filed: May 23, 2025

(30) Foreign Application Priority Data
Oct. 18, 2024 (KR) 10-2024-0143386

(51) Int. Cl. H10B 43/27; G11C 16/04; H01L 23/00; H01L 25/18; H10B 43/10; H10B 43/35; H10B 80/00; H10D 80/30

(52) U.S. Cl. CPC H10B 43/27; G11C 16/0483; H10B 43/10; H10B 43/35; H10B 80/00; H10D 80/30; H10W 90/00; H10W 90/20; H10W 90/24; H10W 90/732; H10W 90/734; H10W 90/752; H10W 90/754; H10W 90/792

(57) ABSTRACT

A three-dimensional semiconductor memory device including a stack structure disposed on a substrate, the stack structure including gate electrodes and interlayered insulating layers alternately stacked along a first direction vertical to an upper surface of the substrate, a semiconductor pattern penetrating the stack structure, and extending along the first direction, a back-gate electrode extending on a side surface of the semiconductor pattern along the first direction, and a back-gate insulating pattern between the semiconductor pattern and the back-gate electrode. The back-gate insulating pattern includes first regions between each of the gate electrodes and the back-gate electrode, and second regions between each of the interlayered insulating layers and the back-gate electrode. In a second direction parallel to the upper surface of the substrate, a thickness of each of the first regions of the back-gate insulating pattern is greater than a thickness of each of the second regions of the back-gate insulating pattern.

### CROSS-REFERENCE TO RELATED APPLICATIONS

This U.S. non-provisional patent application claims priority under 35 U.S.C. § 119 of Korean Patent Application No. 10-2024-0143386, filed on Oct. 18, 2024, the entire contents of which are hereby incorporated by reference.

### BACKGROUND

The present disclosure herein relates to a three-dimensional semiconductor memory device and an electronic system including the same.

A semiconductor device capable of storing a large amount of data is being demanded in an electronic system that requires data storage. Increasing integration of the semiconductor device is being demanded so as not only to increase a data storage capacity, but also to satisfy an excellent function and a low cost demanded by a consumer. In a case of a two-dimensional or planar semiconductor device, since the integration is mainly decided by an area occupied by a unit memory cell, the integration is significantly affected by a level of technology of forming a fine pattern. However, since very expensive equipment is required for forming the fine pattern, the integration of the two-dimensional semiconductor device is increasing, but is still limited. Accordingly, three-dimensional semiconductor memory devices having memory cells three-dimensionally arranged are being proposed.

### SUMMARY

The present disclosure provides a three-dimensional semiconductor memory device with improved reliability and an electronic system including the same.

A technical goal of the inventive concept is not limited to the goal mentioned above, and other technical goals that are not mentioned may be clearly understood from description below by those skilled in the art.

An embodiment of the inventive concept provides a three-dimensional semiconductor memory device including a stack structure disposed on a substrate, the stack structure including gate electrodes and interlayered insulating layers alternately stacked along a first direction vertical to an upper surface of the substrate, a semiconductor pattern penetrating the stack structure, and extending along the first direction, a back-gate electrode extending on a side surface of the semiconductor pattern along the first direction, and a back-gate insulating pattern between the semiconductor pattern and the back-gate electrode, wherein the back-gate insulating pattern includes first regions between each of the gate electrodes and the back-gate electrode, and second regions between each of the interlayered insulating layers and the back-gate electrode, and in a second direction parallel to the upper surface of the substrate, a thickness of each of the first regions of the back-gate insulating pattern is greater than a thickness of each of the second regions of the back-gate insulating pattern.

In an embodiment of the inventive concept, a three-dimensional semiconductor memory device includes a stack structure disposed on a substrate, the stack structure including gate electrodes and interlayered insulating layers alternately stacked along a first direction vertical to an upper surface of the substrate, a semiconductor pattern penetrating the stack structure, and extending along the first direction, a back-gate electrode extending on a side surface of the semiconductor pattern along the first direction, and a back-gate insulating pattern between the semiconductor pattern and the back-gate electrode, wherein the back-gate insulating pattern has a first side surface adjacent to the semiconductor pattern, and a second side surface adjacent to the back-gate electrode, and the first side surface has a wavy profile along the first direction.

In an embodiment of the inventive concept, an electronic system includes a three-dimensional semiconductor memory device, and a controller electrically connected to the three-dimensional semiconductor memory device through an input/output pad, and controlling the three-dimensional semiconductor memory device, wherein the three-dimensional semiconductor memory device includes a stack structure disposed on a substrate, the stack structure including gate electrodes and interlayered insulating layers alternately stacked along a first direction vertical to an upper surface of the substrate, a semiconductor pattern penetrating the stack structure, and extending along the first direction, a back-gate electrode extending on a side surface of the semiconductor pattern along the first direction, and a back-gate insulating pattern between the semiconductor pattern and the back-gate electrode, the back-gate insulating pattern includes first regions between each of the gate electrodes and the back-gate electrode, and second regions between each of the interlayered insulating layers and the back-gate electrode, and in a second direction parallel to the upper surface of the substrate, a thickness of each of the first regions of the back-gate insulating pattern is greater than a thickness of each of the second regions of the back-gate insulating pattern.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1A is a diagram schematically illustrating an electronic system including a three-dimensional semiconductor memory device according to comparative examples of the inventive concept;

FIG. 1B is a diagram schematically illustrating an electronic system including a three-dimensional semiconductor memory device according to some embodiments of the inventive concept;

FIG. 2 is a perspective view schematically illustrating an electronic system including a three-dimensional semiconductor memory device according to some embodiments of the inventive concept;

FIG. 3 is a cross-sectional view for describing a semiconductor package including a semiconductor device according to some embodiments of the inventive concept, and corresponds to a cross-section taken along line I-I′ of FIG. 2;

FIG. 4 is a cross-sectional view for describing a semiconductor package including a semiconductor device according to some embodiments of the inventive concept, and corresponds to a cross-section taken along line II-II′ of FIG. 2;

FIG. 5 is a plan view illustrating a three-dimensional semiconductor memory device according to some embodiments of the inventive concept;

FIG. 6 is a cross-sectional view corresponding to line A-A′ of FIG. 5;

FIG. 7 is an enlarged view corresponding to P1 of FIG. 6;

FIG. 8A is a circuit diagram illustrating a voltage condition in an exemplary program operation of a three-dimensional semiconductor memory device according to embodiments of the inventive concept;

FIG. 8B is a diagram for describing an exemplary program operation of a three-dimensional semiconductor memory device according to embodiments of the inventive concept;

FIG. 9A is a circuit diagram illustrating a voltage condition in an exemplary reading operation of a three-dimensional semiconductor memory device according to embodiments of the inventive concept;

FIG. 9B is a diagram for describing an exemplary reading operation of a three-dimensional semiconductor memory device according to embodiments of the inventive concept;

FIG. 10 is a cross-sectional view corresponding to line A-A′ of FIG. 5; and

FIGS. 11 to 13 are diagrams illustrating a method for manufacturing a three-dimensional semiconductor memory device according to some embodiments of the inventive concept, respectively.

### DETAILED DESCRIPTION

Hereinafter, a semiconductor device according to embodiments of the inventive concept and a method for manufacturing the same will be described in detail with reference to the drawings.

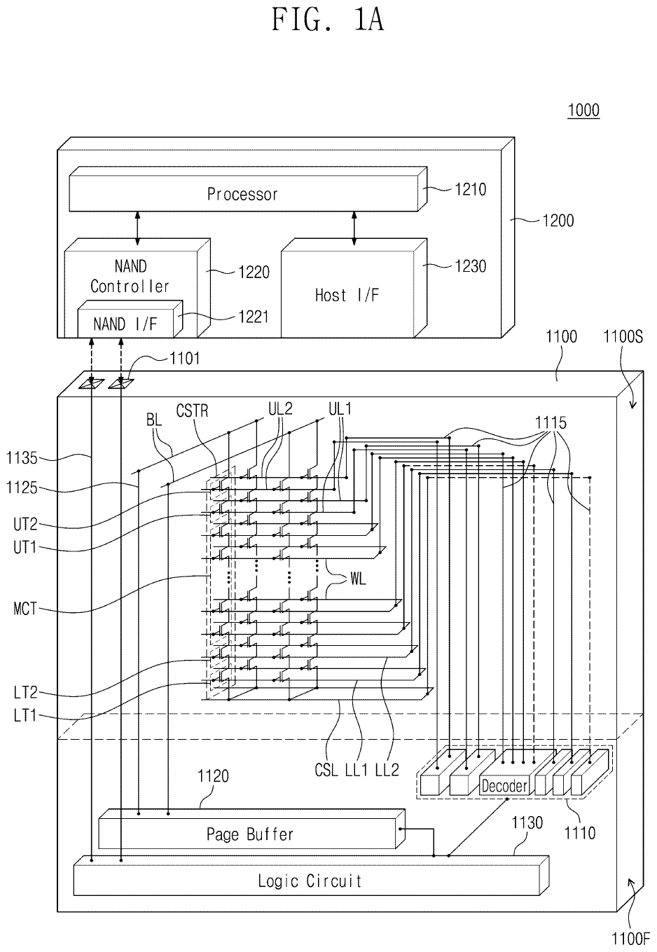

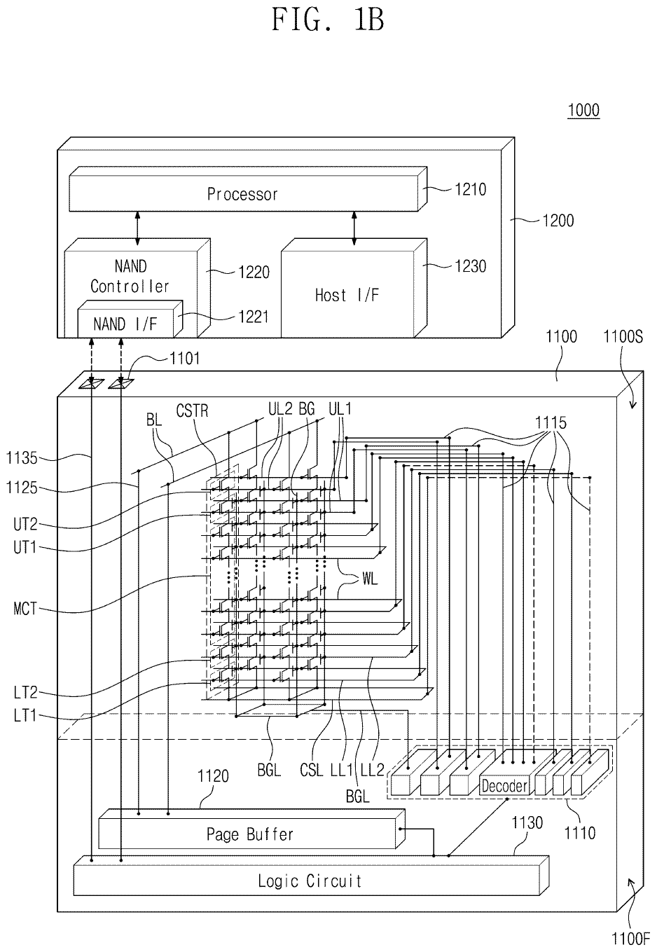

FIG. 1A is a diagram schematically illustrating an electronic system including a three-dimensional semiconductor memory device according to comparative examples of the inventive concept.

Referring to FIG. 1A, an electronic system 1000 according to an embodiment of the inventive concept may include a three-dimensional semiconductor memory device 1100 and a controller 1200 electrically connected to the three-dimensional semiconductor memory device 1100. The electronic system 1000 may be a storage device including one or a plurality of three-dimensional semiconductor memory device 1100 or an electronic device including the storage device. For example, the electronic system 1000 may be a solid state drive (SSD) device, a universal serial bus (USB), a computing system, a medical device, or a communication device including the one or the plurality of three-dimensional semiconductor memory device 1100.

The three-dimensional semiconductor memory device 1100 may be an involatile memory device, and may be, for example, a three-dimensional NAND flash memory device to be described later. The three-dimensional semiconductor memory device 1100 may include a first region 1100F and a second region 1100S on the first region 1100F. However, unlike what is illustrated, the first region 1100F may be disposed beside the second region 1100S. The first region 1100F may be a peripheral circuit region including a decoder circuit 1110, a page buffer 1120 and a logic circuit 1130. The second region 1100S may be a memory cell region including bit lines BL, a common source line CSL, word lines WL, first lines LL1 and LL2, second lines UL1 and UL2, and memory cell strings CSTR between the bit lines BL and the common source line CSL.

In the second region 1100S, each of the memory cell strings CSTR may include first transistors LT1 and LT2 adjacent to the common source line CSL, second transistors UT1 and UT2 adjacent to the bit lines BL, and a plurality of memory cell transistors MCT disposed between the first transistors LT1 and LT2 and the second transistors UT1 and UT2. A number of the first transistors LT1 and LT2 and a number of the second transistors UT1 and UT2 may be variously changed according to embodiments.

For example, the second transistors UT1 and UT2 may include a string selection transistor, and the first transistors LT1 and LT2 may include a ground selection transistor. The first lines LL1 and LL2 may be gate electrodes of the first transistors LT1 and LT2. The word lines WL may be gate electrodes of the memory cell transistors MCT. The second lines UL1 and UL2 may be gate electrodes of the second transistors UT1 and UT2.

For example, the first transistors LT1 and LT2 may include a first erase control transistor LT1 and a ground selection transistor LT2 serially connected to each other. For example, the second transistors UT1 and UT2 may include a string selection transistor UT1 and a second erase control transistor UT2 serially connected to each other. For example, at least one of the first erase control transistor LT1 or the second erase control transistor UT2 may be used in an erase operation of deleting a data stored in the memory cell transistors MCT using a gate-induced drain leakage (GIDL) phenomenon, but an embodiment of the inventive concept is not limited thereto.

The common source line CSL, the first lines LL1 and LL2, the word lines WL and the second lines UL1 and UL2 may be electrically connected to the decoder circuit 1110 through first connection wires 1115 extending from the inside of the first region 1100F to the second region 1100S. The bit lines BL may be electrically connected to the page buffer 1120 through second connection wires 1125 extending from the inside of the first region 1100F to the second region 1100S.

In the first region 1100F, the decoder circuit 1110 and the page buffer 1120 may perform an operation of controlling at least one selection memory cell transistor among a plurality of memory cell transistors MCT. The decoder circuit 1110 and the page buffer 1120 may be controlled by the logic circuit 1130. The three-dimensional semiconductor memory device 1100 may communicate with the controller 1200 through an input/output pad 1101 electrically connected to the logic circuit 1130. The input/output pad 1101 may be electrically connected to the logic circuit 1130 through an input/output connection wire 1135 extending from the inside of the first region 1100F to the second region 1100S.

The controller 1200 may include a processor 1210, a NAND controller 1220 and a host interface 1230. According to embodiments, the electronic system 1000 may include a plurality of three-dimensional semiconductor memory devices 1100, and in this case, the controller 1200 may control the plurality of three-dimensional semiconductor memory devices 1100.

The processor 1210 may control the overall operation of the electronic system 1000 including the controller 1200. The processor 1210 may operate according to a predetermined firmware, and may control the NAND controller 1220 to access the three-dimensional semiconductor memory device 1100. The NAND controller 1220 may include a NAND interface 1221 that processes communication with the three-dimensional semiconductor memory device 1100. A control command for controlling the three-dimensional semiconductor memory device 1100, a data to be recorded in the memory cell transistors MCT of the three-dimensional semiconductor memory device 1100, a data to be read from the memory cell transistors MCT of the three-dimensional semiconductor memory device 1100, or the like may be transferred through the NAND interface 1221. The host interface 1230 may provide a communication function between the electronic system 1000 and an external host. When the control command is received from the external host through the host interface 1230, the processor 1210 may control the three-dimensional semiconductor memory device 1100 in response to the control command.

FIG. 1B is a diagram schematically illustrating the electronic system including the three-dimensional semiconductor memory device according to some embodiments of the inventive concept.

Referring to FIG. 1B, the electronic system including the three-dimensional semiconductor memory device according to some embodiments of the inventive concept may include the same configuration as/a similar configuration to the configuration of the electronic system described with reference to FIG. 1A.

As illustrated in FIG. 1B, the second region 1100S of the electronic system including the three-dimensional semiconductor memory device according to some embodiments of the inventive concept may further include a back-gate line BGL. In addition, in the second region 1100S, each of the memory cell strings CSTR may further include a back-gate electrode BG next to the first transistors LT1 and LT2 and the memory cell transistors MCT in a horizontal direction.

For example, the back-gate electrode BG may be electrically connected to the back-gate line BGL through a separate contact, but an embodiment of the inventive concept is not limited thereto.

The back-gate electrode BG may be electrically connected to the decoder 1110 through the back-gate line BGL extending from the inside of the first region 1100F to the second region 1100S.

The back-gate electrode BG and the back-gate line BGL may be spaced apart from the common source line CSL, the bit lines BL and the word line WL, and may be electrically insulated.

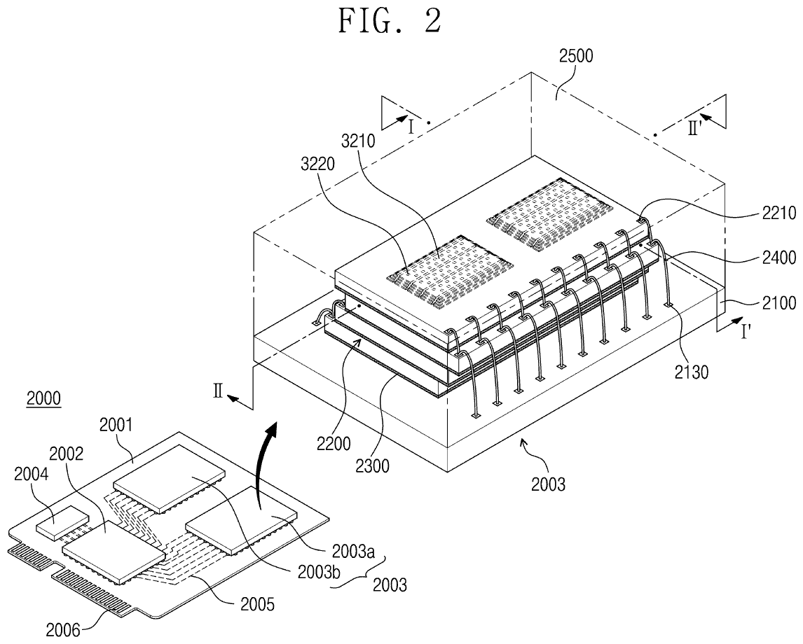

FIG. 2 is a perspective view schematically illustrating an electronic system including a three-dimensional semiconductor memory device according to some embodiments of the inventive concept.

Referring to FIG. 2, an electronic system 2000 according to an embodiment of the inventive concept may include a main substrate 2001, a controller 2002 mounted on the main substrate 2001, at least one semiconductor package 2003 and a DRAM 2004. The semiconductor package 2003 and the DRAM 2004 may be connected to the controller 2002 by wiring patterns 2005 provided to the main substrate 2001.

The main substrate 2001 may include a connector 2006 including a plurality of pins connected to an external host. A number and disposition of the plurality of pins may be changed in the connector 2006 according to communication interface between the electronic system 2000 and the external host. For example, the electronic system 2000 may communicate with the external host according to any one among interfaces such as a universal serial bus (USB), a peripheral component interconnect express (PCI-Express), a serial advanced technology attachment (SATA), M-Phy for a universal flash storage (UFS). For example, the electronic system 2000 may operate by a power supplied by the external host through the connector 2006. The electronic system 2000 may further include a power management integrated circuit (PMIC) that distributes the power supplied by the external host to the controller 2002 and the semiconductor package 2003.

The controller 2002 may write a data to the semiconductor package 2003, read a data from the semiconductor package 2003, and may improve an operation speed of the electronic system 2000.

The DRAM 2004 may be a buffer memory for mitigating a difference of speeds of the semiconductor package 2003, which is a data storage space, and the external host. The DRAM 2004 included in the electronic system 2000 may operate as a kind of a cash memory, and may provide a space for temporarily storing a data in an operation of controlling the semiconductor package 2003. When the DRAM 2004 is included in the electronic system 2000, the controller 2002 may further include a DRAM controller for controlling the DRAM 2004 as well as the NAND controller for controlling the semiconductor package 2003.

The semiconductor package 2003 may include first and second semiconductor packages 2003a and 2003b spaced apart from each other. The first and second semiconductor packages 2003a and 2003b may be each a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on a lower surface of each of the semiconductor chips 2200, connection structures 2400 electrically connecting the package substrate 2100 and the semiconductor chips 2200, and a molding layer 2500 covering the semiconductor chips 2200 and the connection structures 2400 on the package substrate 2100.

The package substrate 2100 may be a printed circuit board including package upper pads 2130. Each of the semiconductor chips 2200 may include input/output pads 2210. Each of the input/output pads 2210 may correspond to the input/output pad 1101 of FIG. 1B. Each of the semiconductor chips 2200 may include gate stack structures 3210 and memory channel structures 3220. Each of the semiconductor chips 2200 may include the three-dimensional semiconductor memory device to be described later.

The connection structures 2400 may be bonding wires electrically connecting the input/output pads 2210 and the package upper pads 2130. Accordingly, in each of the first and second semiconductor packages 2003a and 2003b, the semiconductor chips 2200 may be electrically connected to each other in a bonding wire manner, and may be electrically connected to the package upper pads 2130 of the package substrate 2100. According to embodiments, in each of the first and second semiconductor packages 2003a and 2003b, the semiconductor chips 2200 may be electrically connected to each other by a through silicon via, instead of the connection structures 2400 of the bonding wire manner.

Unlike what is illustrated, the semiconductor chips 2200 and the controller 2002 may be included in one package. The semiconductor chips 2200 and the controller 2002 may be mounted on a separate interposer substrate different from the main substrate 2001, and may be connected to each other by a wire provided to the interposer substrate.

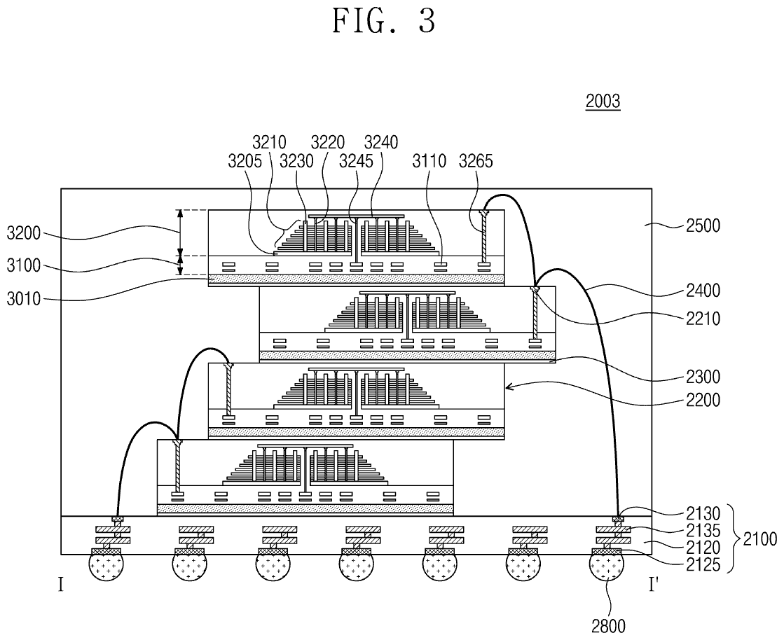

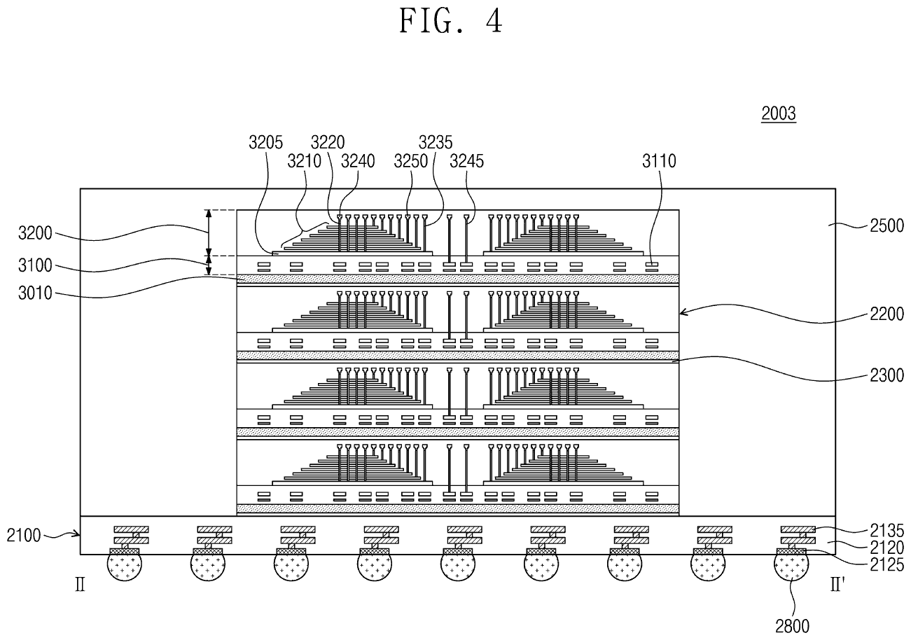

FIGS. 3 and 4 are cross-sectional views for describing the semiconductor package including the semiconductor device according to some embodiments of the inventive concept, and respectively correspond to cross-sections taken along line I-I′ and line II-II′ of FIG. 2.

Referring to FIGS. 3 and 4, the semiconductor package 2003 may include the package substrate 2100, a plurality of semiconductor chips 2200 on the package substrate 2100, and the molding layer 2500 covering the package substrate 2100 and the semiconductor chips 2200.

The package substrate 2100 may include a package substrate body portion 2120, package upper pads 2130 disposed on an upper surface of the package substrate body portion 2120, lower pads 2125 disposed on a lower surface of the package substrate body portion 2120, or exposed through the lower surface of the package substrate body portion 2120, and internal wires 2135 electrically connecting the lower pads 2125 and the upper pads 2130 inside the package substrate body portion 2120. The upper pads 2130 may be electrically connected to a plurality of connection structures 2400. The lower pads 2125 may be connected to the wiring patterns 2005 of the main substrate 2010 of the electronic system 2000 illustrated in FIG. 2 through conductive connection portions 2800.

Each of the semiconductor chips 2200 may include a semiconductor substrate 3010, and a first structure 3100 and a second structure 3200 sequentially stacked on the semiconductor substrate 3010. The first structure 3100 may include a peripheral circuit region including peripheral wires 3110. The second structure 3200 may include a common source line 3205, a gate stack structure 3210 on the common source line 3205, vertical channel structures 3220 and separation structures 3230 penetrating the gate stack structure 3210, bit lines 3240 electrically connected to the vertical channel structures 3220, gate connection wires 3235 electrically connected to the word lines WL (see FIG. 1B) of the gate stack structure 3210 and conductive lines 3250.

Each of the semiconductor chips 2200 may include a penetration wire 3245 electrically connected to the peripheral wires 3110 of the first structure 3100, and extending into the second structure 3200. A subset of penetration wires 3245 may penetrate the gate stack structure 3210, and a subset of penetration wires 3245 may be further disposed outside the gate stack structure 3210. Each of the semiconductor chips 2200 may further include an input/output connection wire 3265 electrically connected to the peripheral wires 3110 of the first structure 3100, and extending into the second structure 3200, and input/output pads 2210 electrically connected to the input/output connection wire 3265.

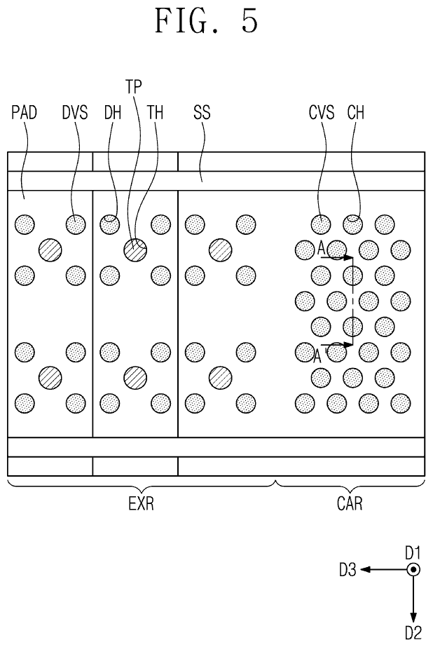

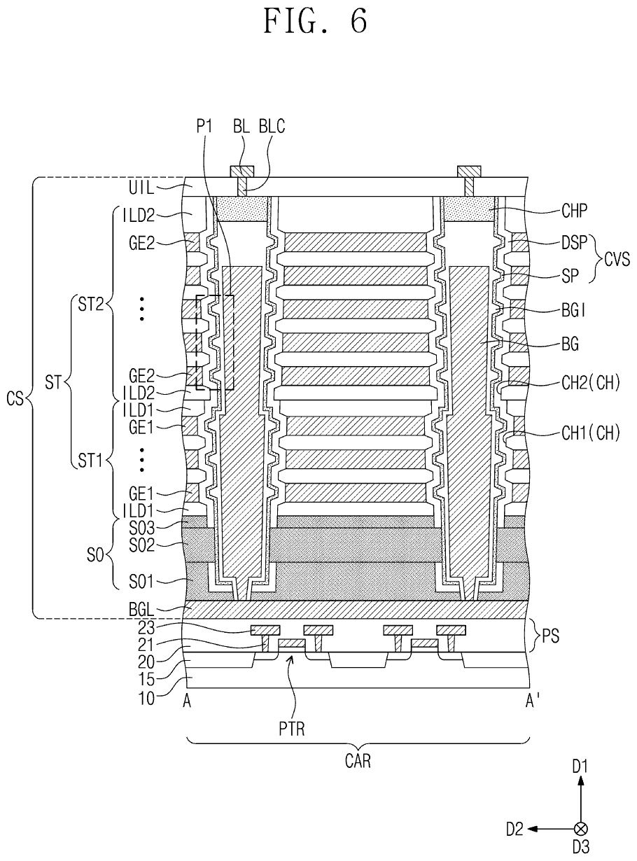

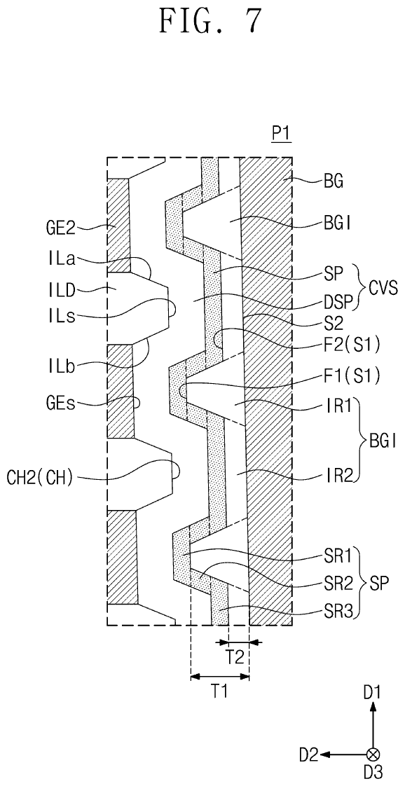

FIG. 5 is a plan view illustrating a three-dimensional semiconductor memory device according to some embodiments of the inventive concept. FIG. 6 is a cross-sectional view corresponding to line A-A′ of FIG. 5. FIG. 7 is an enlarged view corresponding to P1 of FIG. 6.

Referring to FIGS. 5, 6 and 7, the three-dimensional semiconductor memory device according to some embodiments of the inventive concept may include a peripheral circuit structure PS and a cell array structure CS stacked on a substrate 10. The substrate 10 may correspond to the semiconductor substrate 3010 of FIGS. 3 and 4. The peripheral circuit structure PS may correspond to the first structure 3100 of FIGS. 3 and 4. The cell array structure CS may correspond to the second structure 3200 of FIGS. 3 and 4.

For example, the substrate 10 may be a silicon substrate, a silicon-germanium substrate, a germanium substrate, or a single-crystalline epitaxial layer grown on a single-crystalline silicon substrate. A first direction D1 may be vertical to an upper surface of the substrate 10. Each of a second direction D2 and a third direction D3 may be parallel to the upper surface of the substrate 10, and may cross each other. For example, the first to third directions D1, D2 and D3 may be directions crossing each other. An element separation layer 15 may be provided in the substrate 10. The element separation layer 15 may define an active region of the substrate 10.

The peripheral circuit structure PS may include peripheral transistors PTR on the substrate 10, peripheral contact plugs 21, peripheral circuit wires 23 electrically connected to the peripheral transistors PTR through the peripheral contact plugs 21 and a peripheral insulating layer 20 surrounding the same.

The peripheral transistors PTR may be provided on the active region of the substrate 10. The peripheral circuit wires 23 may correspond to the peripheral circuit wires 3110 of FIG. 3 or 4. For example, the peripheral transistors PTR may constitute the decoder circuit 1110 (see FIG. 1B), the page buffer 1120 (see FIG. 1B), the logic circuit 1130 (see FIG. 1B), and the like. For example, each of the peripheral transistors PTR may be an NMOS transistor or PMOS transistor. The peripheral contact plugs 21 and the peripheral circuit wires 23 may include a conductive material such as metal.

The peripheral insulating layer 20 may include a plurality of insulating layers having a multi-layered structure. For example, the peripheral insulating layer 20 may include at least one of silicon oxide, silicon nitride, silicon oxynitride or a low-dielectric material. In the present specification, the low-dielectric material is defined as a material having a lower dielectric constant than silicon oxide.

The cell array structure CS may be provided on the peripheral circuit structure PS. The cell array structure CS may include a source layer SO and a stack structure ST sequentially stacked on the peripheral circuit structure PS, and a bit line BL on the stack structure ST.

The source layer SO may include a first source layer SO1, a second source layer SO2 and a third source layer SO3 sequentially stacked on the peripheral circuit structure PS. The first to third source layers SO1, SO2 and SO3 may include a conductive material. For example, the first to third source layers SO1, SO2 and SO3 may include polysilicon. The second source layer SO2 may be connected to a semiconductor pattern SP to be described later. For example, the second source layer SO2 may correspond to the common source line 3205 of FIGS. 3 and 4.

The stack structure ST may be provided on the third source layer SO3. For example, an extension region insulating layer (not shown) may be provided on the first source layer SO1. The extension region insulating layer may surround the stack structure ST. The extension region insulating layer may include a plurality of insulating layers having a multi-layered structure.

The stack structure ST may be provided in plurality. For example, on a plan view, the plurality of stack structures ST may be spaced apart from each other in the second direction D2, and may each extend in the third direction D3. Hereinafter, for convenience of description, a singular stack structure ST will be described, but description below may be identically applied to other stack structures ST. The stack structure ST may correspond to the gate stack structure 3210 of FIGS. 3 and 4.

The stack structure ST may include a first stack structure ST1 and a second stack structure ST2 sequentially stacked on the source layer SO. The first stack structure ST1 may include first interlayered insulating layers ILD1 and first gate electrodes GE1 alternately stacked, and the second stack structure ST2 may include second interlayered insulating layers ILD2 and second gate electrodes GE2 alternately stacked.

For example, the first and second gate electrodes GE1 and GE2 may include at least one of doped semiconductor (ex, doped silicon, or the like), metal (ex, tungsten, copper, aluminum, or the like), conductive metal nitride (ex, titanium nitride, tantalum nitride, or the like), or transition metal (ex, titanium, tantalum, or the like). For example, the first and second interlayered insulating layers ILD1 and ILD2 may include at least one of silicon oxide, silicon nitride, silicon oxynitride or a low-dielectric material.

For example, although not shown, on a cross-sectional view, the stack structure ST may have a step structure on a cell array extension region EXR along the third direction D3. Each of the first and second gate electrodes GE1 and GE2 may include a pad portion PAD, which is one end portion along the third direction D3. The pad portion PAD may be one region of each of the first and second gate electrodes GE1 and GE2 that constitute the step portion of the stack structure ST.

For another example, although not shown, on a cross-sectional view, the stack structure ST may not have the step structure on the cell array extension region EXR along the third direction D3. In other words, a height of the stack structure ST may be substantially the same, regardless of the third direction D3.

Each of separation patterns SS including an insulating material may extend along the first and third directions D1 and D3. The stack structures ST may be spaced apart from each other in the second direction D2 by each of the separation patterns SS. Each of the separation patterns SS may extend from a cell array region CAR toward the cell array extension region EXR.

A penetration plug TP may penetrate the extension region insulating layer, and may extend along the first direction D1. The penetration plug TP may be electrically connected to the pad portion PAD, and may be electrically connected to the corresponding gate electrode GE1 or GE2 through the pad portion PAD.

At least one first gate electrodes GE1 among the first gate electrodes GE1 may be ground selection lines GSL. The ground selection line GSL may control a ground selection transistor of the first transistors LT1 and LT2 described with reference to FIG. 1B. For example, the ground selection line GSL may be located under the stack structure ST.

At least one second gate electrodes GE2 among the second gate electrodes GE2 may be string selection lines SSL. The string selection line SSL may control a string selection transistor of the second transistors UT1 and UT2 described with reference to FIG. 1B. For example, the string selection line SSL may be located on the stack structure ST.

Channel holes CH may penetrate the stack structure ST of the cell array structure CS in the cell array region CAR. For example, each of the channel holes CH may include a first channel hole CH1 penetrating the first stack structure ST1, and a second channel hole CH2 penetrating the second stack structure ST2. For example, each of the first and second channel holes CH1 and CH2 may have a width in the second direction D2 and/or the third direction D3 increasing in the first direction D1. The first and second channel holes CH1 and CH2 may be connected to each other. On a boundary on which the first and second channel holes CH1 and CH2 are connected to each other, a diameter of the second channel hole CH2 may be smaller than a diameter of the first channel hole CH1. The first and second channel holes CH1 and CH2 may have a step on the boundary on which the first and second channel holes CH1 and CH2 are connected to each other, but an embodiment of the inventive concept is not limited thereto.

In the cell array region CAR, cell vertical structures CVS may penetrate the stack structure ST in the first direction D1, and may conformally cover the channel hole CH. The cell vertical structures CVS may correspond to the memory channel structures 3220 of FIGS. 3 and 4.

Dummy holes DH may penetrate at least one of the stack structure ST or the extension region insulating layer in the cell array extension region EXR in the first direction D1. Dummy vertical structures DVS may respectively fill the dummy holes DH.

Each of the cell vertical structures CVS may include a data storage pattern DSP and a semiconductor pattern SP sequentially conformally covering an inner sidewall of the channel hole CH.

The semiconductor pattern SP may penetrate the stack structure ST, and may extend along the first direction D1. For example, the semiconductor pattern SP may include a semiconductor material doped with an impurity, an intrinsic semiconductor material in a state in which the intrinsic semiconductor material is not doped with an impurity, or a polycrystalline semiconductor material.

The data storage pattern DSP may be interposed between the first and second gate electrodes GE1 and GE2 and the semiconductor pattern SP. The data storage pattern DSP may penetrate the stack structure ST, and may extend between the first and second gate electrodes GE1 and GE2 and the semiconductor pattern SP in the first direction D1.

For example, the three-dimensional semiconductor memory device may store and/or change a data in the data storage pattern DSP by a Fowler-Nordheim tunneling phenomenon induced by a voltage difference between the semiconductor pattern SP and the first and second gate electrodes GE1 and GE2. In this case, the data storage pattern DSP may include a blocking insulating layer (not shown), a charge storage layer (not shown) and a tunneling insulating layer (not shown) sequentially stacked on the inner sidewall of the channel hole CH. For example, the blocking insulating layer and the tunneling insulating layer may include silicon oxide, and the charge storage layer may include at least one of silicon nitride or silicon oxynitride.

For another example, the data storage pattern DSP may include a ferroelectric layer (not shown). Accordingly, since the three-dimensional semiconductor memory device has a polarization state changed by an electric field applied to the ferroelectric layer, a data may be stored and/or changed in the data storage pattern DSP. For example, the ferroelectric layer may include at least one of HfO₂, HfSiO₂ (Si-doped HfO₂), HfAlO₂ (Al-doped HfO₂), HfYO₂ (Y-doped HfO₂), HfSrO₂ (Sr-doped HfO₂), HfGdO₂ (Gd-doped HfO₂), HfLaO₂ (La-doped HfO₂), HfSiON, HfZnO, HfZrO₂, ZrO₂, ZrSiO₂, HfZrSiO₂, ZrSiON, LaAlO, BaTiO₃, AlScN, HfDyO₂ or HfScO₂. For example, the data storage pattern DSP may include at least one of an insulating material or a conductive material between the ferroelectric layer and the first and second gate electrodes GE1 and GE2. The insulating material may be a single layer or a plurality of layers. When the insulating material is provided in plurality, some thereof may include nitride. For example, the data storage pattern DSP may include an insulating material between the ferroelectric layer and the semiconductor pattern SP. The insulating material may be a single layer or a plurality of layers. When the insulating material is provided in plurality, some thereof may include nitride.

A back-gate electrode BG may be provided inside the channel hole CH. The back-gate electrode BG may be provided on a side surface of the semiconductor pattern SP, and may extend along the first direction D1. An upper surface of the back-gate electrode BG may be located at a lower vertical level (i.e., along the first direction D1) than a lower surface of the string selection lines SSL of the second gate electrodes GE2. For example, the back-gate electrode BG may include at least one of a metal material or doped polysilicon. The back-gate electrode BG may correspond to the back-gate electrode BG described with reference to FIG. 1B. The back-gate electrode BG may correspond to the back-gate electrode BG provided in the memory channel structure 3220 described with reference to FIG. 3 or 4.

A back-gate insulating pattern BGI may extend between the semiconductor pattern SP and the back-gate electrode BG along the first direction D1. The back-gate insulating pattern BGI may be interposed between the back-gate electrode BG and a channel pad CHP to be described later. The back-gate insulating pattern BGI may include an insulating material, and the back-gate electrode BG and the semiconductor pattern SP, and the back-gate electrode BG and the channel pad CHP may be spaced apart from each other by the back-gate insulating pattern BGI.

The back-gate insulating pattern BGI may include first regions IR1 between the first and second gate electrodes GE1 and GE2 and the back-gate electrode BG, and second regions IR2 between the first and second interlayered insulating layers ILD1 and ILD2 and the back-gate electrode BG. The first regions IR1 and the second regions IR2 of the back-gate insulating pattern BGI may be alternately disposed along the first direction D1. It is illustrated in the drawing that the first regions IR1 of the back-gate insulating pattern BGI are interposed, except for some of the second gate electrodes GE2 corresponding to the string selection line SSL, between the remaining gate electrodes GE1 and GE2 and the back-gate electrode BG, but an embodiment of the inventive concept is not limited thereto. A number of the first regions IR1 of the back-gate insulating pattern BGI may be variously changed.

The semiconductor pattern SP may include first semiconductor regions SR1, second semiconductor regions SR2, and third semiconductor regions SR3 that are adjacent to one or more of the first regions IR1 and the second regions IR2 of the back-gate insulating pattern BGI. For example, the first semiconductor regions SR1, second semiconductor regions SR2, and third semiconductor regions SR3 may contact one or more of the first regions IR1 and the second regions IR2 of the back-gate insulating pattern BGI. At least a portion of the first semiconductor region SR1 may be disposed between the first regions IR1 of the back-gate insulating pattern BGI and the first and second gate electrodes GE1 and GE2. The second semiconductor regions SR2 may be disposed between the first regions IR1 of the back-gate insulating pattern BGI and the first and second gate electrodes GE1 and GE2. A first portion of the third semiconductor regions SR3 may be disposed between the first regions IR1 of the back-gate insulating pattern BGI and the first and second gate electrodes GE1 and GE2. A second portion of the third semiconductor regions SR3 may be disposed between the second regions IR2 of the back-gate insulating pattern BGI and the first and second interlayered insulating layers ILD1 and ILD2. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting,” “in contact with,” or “contact” another element, there are no intervening elements present at the point of contact.

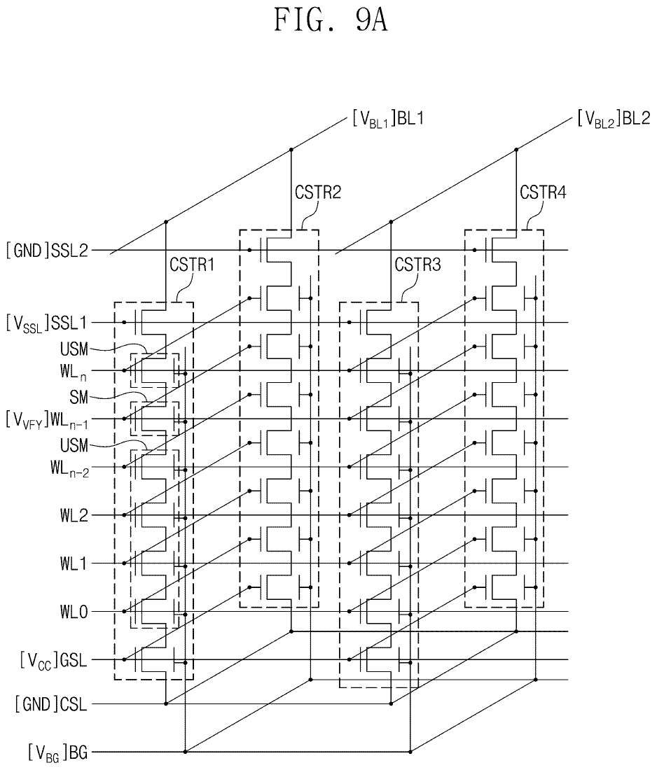

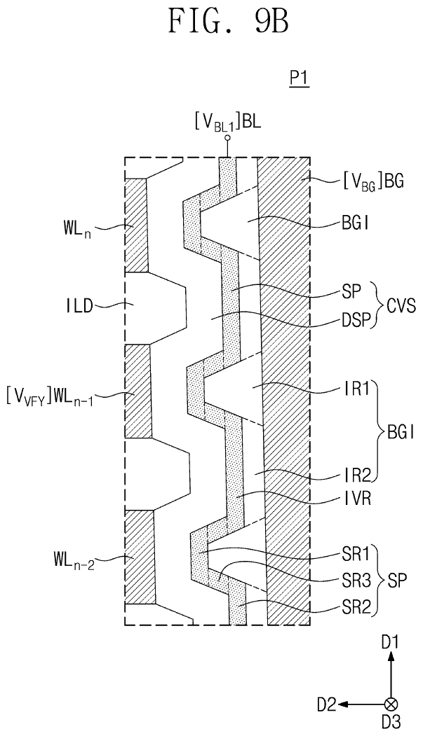

With respect to a direction parallel to the upper surface of the substrate 10 (e.g., direction D2), a thickness T1 of the first region IR1 of the back-gate insulating pattern BGI may be greater than a thickness T2 of the second region IR2. Accordingly, a distance between the back-gate electrode BG and the first semiconductor region SR1 of the semiconductor pattern SP may become greater than a distance between the back-gate electrode BG and the second semiconductor region SR2 of the semiconductor pattern SP, and a distance between the back-gate electrode BG and the third semiconductor region SR3 of the semiconductor pattern SP. In other words, an equivalent oxide thickness (EOT) between the back-gate electrode BG and the first semiconductor region SR1 of the semiconductor pattern SP may become greater than an equivalent oxide thickness (EOT) between the back-gate electrode BG and the second semiconductor region SR2 of the semiconductor pattern SP, and an equivalent oxide thickness (EOT) between the back-gate electrode BG and the third semiconductor region SR3 of the semiconductor pattern SP. An effect of the inventive concept according to this will be described with reference to FIGS. 9A and 9B.

The back-gate insulating pattern BGI may have a first side surface S1 adjacent to the semiconductor pattern SP and a second side surface S2 adjacent to the back-gate electrode BG. Each of the first side surface S1 and the second side surface S2 may face a direction parallel to the upper surface of the substrate 10. The first side surface S1 of the back-gate insulating pattern BGI may include a first surface F1 adjacent to the first semiconductor region SR1 of the semiconductor pattern SP and a second surface F2 adjacent to the second semiconductor region SP2 of the semiconductor pattern SP. The first surface F1 of the first side surface S1 may protrude, in a direction parallel to the upper surface of the substrate 10, more than the second surface F2. Accordingly, the first side surface S1 of the back-gate insulating pattern BGI may have a wavy (e.g., having a series of protrusions and recessions, non-linear) profile along the first direction D1. A distance between the back-gate electrode BG and the first surface F1 of the first side surface S1 of the back-gate insulating pattern BGI may be greater than a distance between the back-gate electrode BG and the second surface F2 of the first side surface S1. The semiconductor pattern SP may be conformally formed on the first side surface S1 of the back-gate insulating pattern BGI. The first surface F1 of the first side surface S1 may contact the first semiconductor region SR1 of the semiconductor pattern SP. The second surface F2 of the first side surface S1 may contact the third semiconductor region SR3 of the semiconductor pattern SP.

The second side surface S2 of the back-gate insulating pattern BGI may be in contact with a side surface of the back-gate electrode BG. Accordingly, the second side surface S2 may follow a profile of the side surface of the back-gate electrode BG. In the present specification, the wording, “A conformally formed on B” and “A follows a profile of B” with respect to components A and B adjacent to each other may mean that when A has a linear profile, B also has a linear profile, or when A has a profile concave toward the inside of A, B has a profile convex toward the inside of A. For example, the side surface of the back-gate electrode BG may substantially have a linear profile, and thus the second side surface S2 of the back-gate insulating pattern BGI may have a linear profile.

A side surface GEs of each of the first and second gate electrodes GE1 and GE2 may be recessed in a direction parallel to the upper surface of the substrate 10 more than a side surface ILs of each of the first and second interlayered insulating layers ILD1 and ILD2. Accordingly, the side surface ILs of each of the first and second interlayered insulating layers ILD1 and ILD2 may protrude, in the direction parallel to the upper surface of the substrate 10, more than the side surface GEs of each of the first and second gate electrodes GE1 and GE2. Accordingly, each of the data storage pattern DSP and the semiconductor pattern SP provided on the side surfaces GEs of the first and second gate electrodes GE1 and GE2 and the side surfaces ILs of the first and second interlayered insulating layers ILD1 and ILD2 may have a wavy profile along the first direction D1. The data storage pattern DSP may be partially inserted between the first interlayered insulating layers ILD1 and between the second interlayered insulating layers ILD2. The data storage pattern DSP may be partially in contact with upper surfaces ILa and lower surfaces ILb of the first and second interlayered insulating layers ILD1 and ILD2.

The back-gate line BGL may be interposed between the peripheral circuit structure PS and the source layer SO. The back-gate line BGL may be connected to the back-gate electrode BG. The back-gate line BGL may include a conductive material. The back-gate line BGL may correspond to the back-gate line BGL described with reference to FIG. 1B.

The channel pad CHP may be provided on the back-gate insulating pattern BGI. The channel pad CHP may fill a remaining portion of the channel hole CH, and may be surrounded by the semiconductor pattern SP and the data storage pattern DSP. For example, the channel pad CHP may include a semiconductor material doped with an impurity, an intrinsic semiconductor material in a state in which the intrinsic semiconductor material is not doped with an impurity, or a polycrystalline semiconductor material.

An upper insulating layer UIL may be provided on the stack structure ST. For example, the upper insulating layer UIL may include a plurality of insulating layers having a multi-layered structure.

A bit line BL may be provided on the upper insulating layer UIL. The bit line BL may correspond to the bit line 3240 of FIGS. 3 and 4. A bit line contact BLC may penetrate the upper insulating layer UIL, and may be in contact with an upper surface of the channel pad CHP. The bit line contact BLC may be interposed between the bit line BL and the channel pad CHP.

For example, the bit line BL and the bit line contact BLC may include a conductive material such as metal. Accordingly, the bit line BL may be electrically connected to the channel pad CHP through the bit line contact BLC.

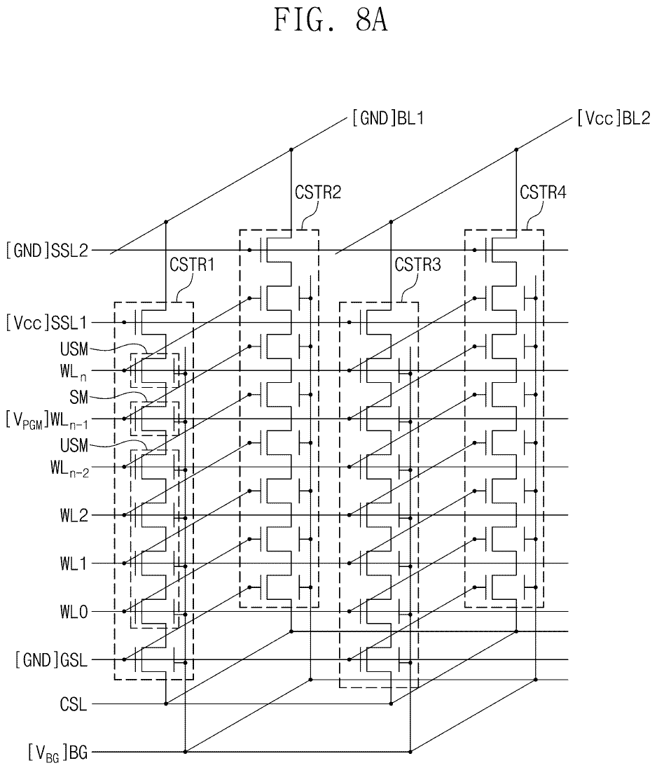

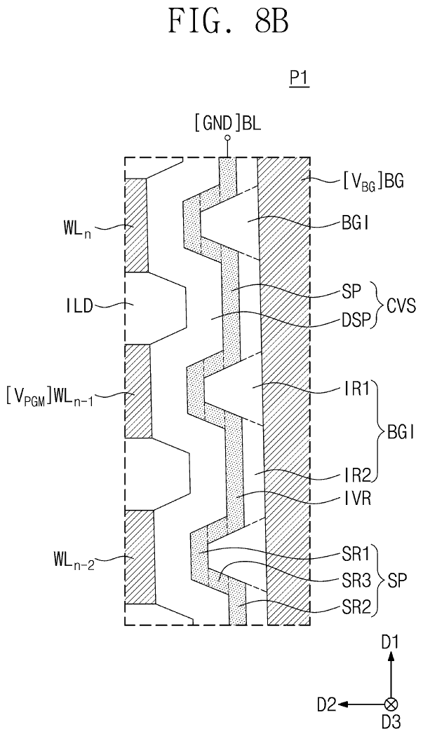

FIG. 8A is a circuit diagram illustrating a voltage condition in an exemplary program operation of a three-dimensional semiconductor memory device according to embodiments of the inventive concept. FIG. 8B is a diagram for describing the exemplary program operation of the three-dimensional semiconductor memory device according to embodiments of the inventive concept.

Referring to FIGS. 8A and 8B, when a program is operated, a first cell string CSTR1 may be selected, and second to fourth cell strings CSTR2, CSTR3 and CSTR4 may not be selected. The first cell string CSTR1 may include one selected memory cell SM and a plurality of unselected memory cells USM. The second to fourth cell strings CSTR2, CSTR3 and CSTR4 may not include the selected memory cell SM.

The first and second cell strings CSTR1 and CSTR2 may share one first string selection line SSL1. The third and fourth cell strings CSTR3 and CSTR4 may share one second string selection line SSL2. The first to fourth cell strings CSTR1, CSTR2, CSTR3 and CSTR4 may share one selected word line WLn-1 and unselected word lines WL0, WL1, WL2, WLn-2 and WLn. The first to fourth cell strings CSTR1, CSTR2, CSTR3 and CSTR4 may share one ground selection line GSL. Each of the first to fourth cell strings CSTR1, CSTR2, CSTR3 and CSTR4 may be connected to the back-gate electrode BG. Each of the first cell string CSTR1 and the third cell string CSTR3 may be connected to a first bit line BL1. Each of the second cell string CSTR2 and the fourth cell string CSTR4 may be connected to a second bit line BL2. The first to fourth cell strings CSTR1, CSTR2, CSTR3 and CSTR4 may be connected to a common source line CSL (for example, the second source layer SO2 of FIG. 6).

A string selection transistor of the first cell string CSTR1 may be turned on. In other words, a difference between a voltage applied to the first string selection line SSL1 and a voltage applied to the first bit line BL1 may be greater than a size of a voltage that may turn on the string selection transistor.

The string selection transistor of each of the second to fourth cell strings CSTR2, CSTR3 and CSTR4 may be turned off. A difference between a voltage applied to the second bit line BL2 and a voltage applied to the first string selection line SSL1 may be smaller than a size of a voltage that may turn on the string selection transistor. A difference between the voltage applied to the second string selection line SSL2 and the voltage applied to each of the first bit line BL1 and the second bit line BL2 may be smaller than the size of the voltage that may turn on the string selection transistor.

For example, a power voltage Vcc may be applied to the first string selection line SSL1, and a ground voltage GND may be applied to the second string selection line SSL2. The ground voltage GND may be applied to the first bit line BL1, and the power voltage Vcc may be applied to the second bit line BL2.

A ground selection transistor of each of the first to fourth cell strings CSTR1, CSTR2, CSTR3 and CSTR4 may be turned off. For example, the ground voltage GND may be applied to the ground selection line GSL.

In addition, a program voltage V_{PGM} may be applied to a selected word line WLn-1. Each of unselected word lines WL0, WL1, WL2, WLn-2 and WLn may be floated. For example, when a data is recorded in the selected word line WLn-1, a size and/or application timing of a voltage applied to unselected word lines WLn-2 and WLn may be controlled so as to prevent a breakdown phenomenon between the selected word line WLn-1 and the unselected word lines WLn-2 and WLn adjacent to the selected word line WLn-1 among the unselected word lines WL0, WL1, WL2, WLn-2 and WLn. For example, when a data is recorded in the selected word line WLn-1, the size and/or the application timing of the voltage applied to the unselected word lines WLn-2 and WLn may be controlled so as to prevent the data from unintentionally being recorded in the unselected word lines WLn-2 and WLn adjacent to the selected word line WLn-1 among the unselected word lines WL0, WL1, WL2, WLn-2 and WLn.

A back-gate voltage V_{BG} may be applied to the back-gate electrode BG through the back-gate line BGL. The ground voltage GND may be applied to the ground selection line GSL. Accordingly, the ground selection transistor of each of the first to fourth cell strings CSTR1, CSTR2, CSTR3 and CSTR4 may be turned off.

When the program is operated under the above voltage condition, although the unselected word lines WL0, WL1, WL2, WLn-2 and WLn are floated, since the back-gate voltage V_{BG} is applied to the back-gate electrode BG, an inversion region IVR may be formed in the semiconductor pattern SP. Accordingly, the ground voltage GND applied to the first bit line BL1 may be transferred to the inversion region IVR in the semiconductor pattern SP of the first cell string CSTR1. As a result, a data may be recorded in the selected memory cell SM by a difference between the program voltage V_{PGM} applied to the selected word line WLn-1 and the ground voltage GND in the semiconductor pattern SP in the first cell string CSTR1.

An additional voltage applied to the unselected word lines WL0, WL1, WL2, WLn-2 and WLn so as to form the inversion region IVR in the semiconductor pattern SP of the first cell string CSTR1 may not be needed. Accordingly, an unintentional data may not be recorded in the unselected memory cells USM by the additional voltage applied to the unselected word lines WL0, WL1, WL2, WLn-2 and WLn. As a result, a disturbance phenomenon generated during an operation of programming the three-dimensional semiconductor memory device may be prevented, and thus reliability of the three-dimensional semiconductor memory device may be improved.

When the program is operated under the voltage condition, an inversion region (not shown) may be formed in the semiconductor pattern (not shown) in the second to fourth cell strings CSTR2, CSTR3 and CSTR4 by the back-gate voltage V_{BG} applied to the back-gate electrode BG. A voltage in the inversion region may be boosted by the back-gate voltage V_{BG}. A difference between the program voltage V_{PGM} applied to the selected word line WLn-1 and a voltage in the inversion region increased by the back-gate voltage V_{BG} may be smaller than a size of a voltage capable of recording a data in a memory cell. Accordingly, an unintended data may not be recorded in the memory cell of each of the second to fourth cell strings CSTR2, CSTR3 and CSTR4 that share the selected word line WLn-1. As a result, a disturbance phenomenon generated during an operation of programming the three-dimensional semiconductor memory device may be prevented, and thus reliability of the three-dimensional semiconductor memory device may be improved.

FIG. 9A is a circuit diagram illustrating a voltage condition in an exemplary reading operation of the three-dimensional semiconductor memory device according to embodiments of the inventive concept. FIG. 9B is a diagram for describing an exemplary reading operation of the three-dimensional semiconductor memory device according to embodiments of the inventive concept.

Referring to FIGS. 9A and 9B, each of the first and second cell strings CSTR1 and CSTR2 may be selected during a reading operation. Each of the first and second cell strings CSTR1 and CSTR2 may include the one selected memory cell SM. Each of the third and fourth cell strings CSTR3 and CSTR4 may not be selected during the reading operation.

A string selection transistor of each of the first and second cell strings CSTR1 and CSTR2 may be turned on. For example, a string selection voltage V_{SSL} may be applied to the first string selection line SSL1, and a first bit line voltage V_{BL1} may be applied to the first bit line BL1, and a second bit line voltage V_{BL2} may be applied to the second bit line BL2. Each of a difference between the string selection voltage V_{SSL} and the first bit line voltage V_{BL1}, and a difference between the string selection voltage V_{SSL} and the second bit line voltage V_{BL2} may be greater than a size of a voltage that may turn on the string selection transistor. For example, the first bit line voltage V_{BL1} and the second bit line voltage V_{BL2} may be substantially the same as each other.

The string selection transistor of each of the third and fourth cell strings CSTR3 and CSTR4 may be turned off. For example, the ground voltage GND may be applied to the second string selection line SSL2.

The ground selection transistor of each of the first to fourth cell strings CSTR1, CSTR2, CSTR3 and CSTR4 may be turned on. For example, the power voltage Vcc may be applied to the ground selection line GSL, and the ground voltage GND may be applied to the common source line CSL.

A verification voltage V_{VFY} may be applied to the selected word line WLn-1. Each of the unselected word lines WL0, WL1, WL2, WLn-2 and WLn may be floated. The back-gate voltage V_{BG} may be applied to the back-gate electrode BG through the back-gate line BGL. For example, the back-gate voltage V_{BG} described with reference to FIGS. 9A and 9B may have values different from the back-gate voltage V_{BG} specifically described with reference to FIGS. 8A and 8B.

During the reading operation under the voltage condition, although the unselected word lines WL0, WL1, WL2, WLn-2 and WLn are floated, since the back-gate voltage V_{BG} is applied to the back-gate electrode BG, the inversion region IVR may be formed in the semiconductor pattern SP. A data of the selected memory cell SM of each of the first and second cell strings CSTR1 and CSTR2 may be read by applying the verification voltage V_{VFY} to the selected word line WLn-1, and measuring current that flows in the semiconductor pattern SP.

A degree of formation of the inversion region IVR in the semiconductor pattern SP according to the back-gate voltage V_{BG} may be changed depending on an equivalent oxide thickness (EOT) between the back-gate electrode BG and the semiconductor pattern SP. In other words, the degree of formation of the inversion region IVR according to the back-gate voltage V_{BG} may be changed depending on thickness of a back-gate insulating pattern BGI between the back-gate electrode BG and the semiconductor pattern SP. For example, when a thickness of the back-gate insulating pattern BGI becomes smaller, the inversion region IVR according to the back-gate voltage V_{BG} may be easily formed. Alternatively, when the thickness of the back-gate insulating pattern BGI becomes greater, the inversion region IVR according to the back-gate voltage V_{BG} may be difficultly formed.

During the reading operation, when the verification voltage V_{VFY} of the selected word line WLn-1 is smaller than a threshold voltage, the inversion region IVR in the first semiconductor regions SR1 of the semiconductor pattern SP may be canceled out by a voltage applied to the selected word line WLn-1. When the verification voltage V_{VFY} is lower than the threshold voltage, but when the inversion region IVR is not canceled out, an unintended current (hereinafter, an off current) may flow in the semiconductor pattern SP. As a result, reliability of the reading operation may be deteriorated.

As described above, when the thickness of the back-gate insulating pattern BGI becomes smaller, the inversion region IVR according to the back-gate voltage V_{BG} may be easily formed, and although the verification voltage V_{VFY} is smaller than the threshold voltage, the inversion region IVR in the first semiconductor regions SR1 may not be canceled out. In other words, when a distance between the back-gate electrode BG and the first semiconductor regions SR1 becomes closer, and when the verification voltage V_{VFY} is smaller than the threshold voltage, the off current may increase. In order to solve limitation described above, the thickness of the back-gate insulating pattern BGI may be increased. Accordingly, when the verification voltage V_{VFY} is smaller than the threshold voltage, the inversion region IVR in the first semiconductor regions SR1 may be easily canceled out.

However, when the thickness of the back-gate insulating pattern BGI becomes greater, the inversion region IVR may not be easily formed. Accordingly, when the verification voltage V_{VFY} is greater than the threshold voltage, the current (hereinafter, an on current) flowing in the semiconductor pattern SP may become smaller. As a result, reliability of the reading operation may be deteriorated.

According to the inventive concept, a thickness T1 of the first region IR1 of the back-gate insulating pattern BGI may be greater than a thickness T2 of the second region IR2. Accordingly, a distance between the back-gate electrode BG and the first semiconductor region SR1 of the semiconductor pattern SP becomes greater than a distance between the back-gate electrode BG and the third semiconductor region SR3 of the semiconductor pattern SP. As a result, when the verification voltage V_{VFY} is smaller than the threshold voltage, the inversion region IVR in the first semiconductor region SR1 formed by the back-gate voltage V_{BG} may be easily canceled out by the verification voltage V_{VFY}. Accordingly, when the verification voltage V_{VFY} is smaller than the threshold voltage, the off current may be reduced. In addition, when the verification voltage V_{VFY} is greater than the threshold voltage, the inversion region IVR in the third semiconductor region SR3 may be more easily formed by the back-gate voltage V_{BG}. Accordingly, when the verification voltage V_{VFY} is greater than the threshold voltage, the on current may increase. Since the inventive concept has a feature above, the off current may be reduced, and at the same time, the on current may increase during the reading operation. Accordingly, the reliability of the three-dimensional semiconductor memory device may be improved.

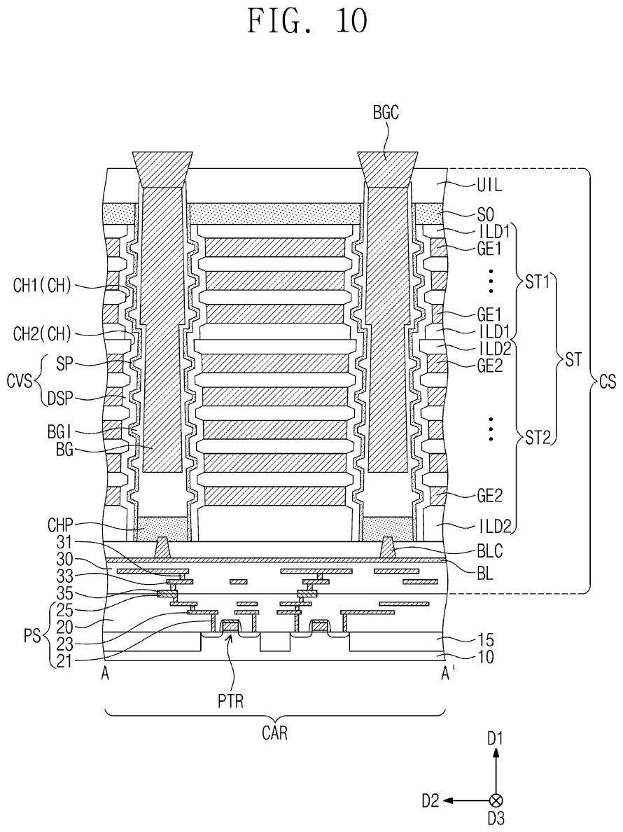

FIG. 10 is a cross-sectional view corresponding to line A-A′ of FIG. 5.

Referring to FIG. 10, unlike what is described with reference to FIGS. 5 and 6, the cell array structure CS may be inverted on the peripheral circuit structure PS. Accordingly, components provided under the cell array structure CS among components of the cell array structure CS described with reference to FIGS. 5 and 6 may be provided on the cell array structure CS. Likewise, components provided on the cell array structure CS among the components of the cell array structure CS described with reference to FIGS. 5 and 6 may be provided under the cell array structure CS.

The peripheral circuit structure PS may further include first bonding pads 25 electrically connected to the peripheral circuit wires 23. The cell array structure CS may include second bonding pads 35 in contact with the first bonding pads 25 between the stack structure ST and the peripheral circuit structure PS, cell circuit wires 33 and cell contact plugs 31 electrically connected to the second bonding pads 35, a bit line BL extending along the second direction D2, a bit line contact BLC between the bit line BL and the channel pad CHP and a cell insulating layer 30 surrounding the same.

A source layer SO may be provided on the cell array structure CS, and may cover an upper surface of the stack structure ST. The source layer SO may be in contact with and may be electrically connected to an upper portion of the semiconductor pattern SP. An upper surface of the back-gate insulating pattern BGI may be located at a higher level than an upper surface of the semiconductor pattern SP.

An upper insulating layer UIL may be provided on the source layer SO. The back-gate contact BGC may at least partially penetrate the upper insulating layer UIL, and may be connected to an upper surface of the back-gate electrode BG. Although not shown, the back-gate contact BGC may be connected to the decoder circuit 1110 described with reference to FIG. 1B through a separate conductive line.

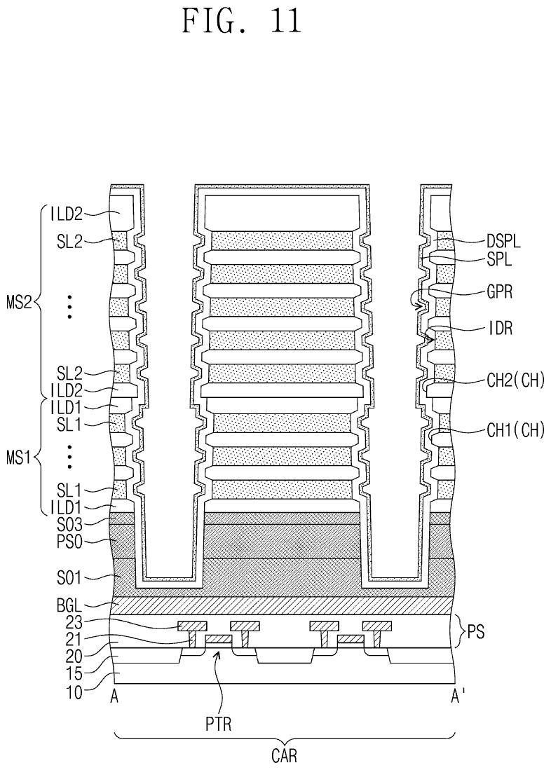

Hereinafter, a method for manufacturing a three-dimensional semiconductor memory device according to some embodiments of the inventive concept will be described with reference to FIGS. 11 to 13. In order to simplify description, duplicate descriptions of those described above will be omitted, and a difference from those described above will be mainly described.

FIGS. 11 to 13 are diagrams illustrating the method for manufacturing a three-dimensional semiconductor memory device according to some embodiments of the inventive concept. Specifically, FIGS. 11 to 13 are cross-sectional views corresponding to line A-A′ of FIG. 5, respectively.

Referring to FIGS. 5 and 11, a peripheral circuit structure PS may be formed on the substrate 10. Forming the peripheral circuit structure PS may include forming an element separation layer 15 inside a substrate 10, forming peripheral transistors PTR on an active region of the substrate 10 defined by the element separation layer 15, and forming peripheral contact plugs 21 electrically connected to the peripheral transistors PTR, peripheral circuit wires 23, and a peripheral insulating layer 20 covering these. A back-gate line BGL may be formed on the peripheral circuit structure PS.

A first source layer SO1, a preliminary source layer PSO, and a third source layer SO3 may be sequentially formed on the peripheral insulating layer 20. For example, the preliminary source layer PSO may include an insulating material. A first mold structure MS1 may be formed on the third source layer SO3. The first mold structure MS1 may include the first interlayered insulating layers ILD1 and a first sacrificial layers SL1 alternately stacked. The first interlayered insulating layers ILD1 and the first sacrificial layers SL1 may include different insulating materials. For example, the first interlayered insulating layers ILD1 may include silicon oxide, and the first sacrificial layers SL1 may include silicon nitride.

A first channel hole CH1 may be formed so as to penetrate the first interlayered insulating layers ILD1 and the first sacrificial layers SL1 in the first direction D1. In this case, components such as the dummy holes DH (see FIG. 5) and the penetration hole TH (see FIG. 5) may be formed together, but an embodiment of the inventive concept is not limited thereto.

A second mold structure MS2 may be formed on the first mold structure MS1. The second mold structure MS2 may include second interlayered insulating layers ILD2 and second sacrificial layers SL2 alternately stacked. Characteristics of the second interlayered insulating layers ILD2 and the second sacrificial layers SL2 may be the same as/similar to the first interlayered insulating layers ILD1 and the first sacrificial layers SL1.

Thereafter, a second channel hole CH2 may be formed so as to penetrate second interlayered insulating layers ILD2 and second sacrificial layers SL2 in the first direction D1. In this case, components such as the dummy holes DH (see FIG. 5) and the penetration hole TH (see FIG. 5) may be formed together, but an embodiment of the inventive concept is not limited thereto. The first and second channel holes CH1 and CH2 may constitute a channel hole CH.

Thereafter, a process of recessing side surfaces of each of the first sacrificial layers SL1 and the second sacrificial layers SL2 may be performed. Accordingly, an indent region IDR may be formed on the side surfaces of each of the first sacrificial layers SL1 and the second sacrificial layers SL2. As a result, the side surfaces of each of the first sacrificial layers SL1 and the second sacrificial layers SL2 may be recessed in a direction parallel to an upper surface of the substrate 10 more than side surfaces of each of the first and second interlayered insulating layers ILD1 and ILD2.

A data storage layer DSPL may be formed so as to conformally cover each of the channel hole CH and the indent region IDR. Accordingly, the data storage layer DSPL may be formed so as to have a wavy profile in the channel holes CH along the first direction D1. A semiconductor layer SPL may be formed on the data storage layer DSPL. The semiconductor layer SPL may be formed so as to have a wavy profile in the channel holes CH along the first direction D1 due to the profile of the data storage layer DSPL. Since the semiconductor layer SPL has the profile, a gapfill region GPR may be formed on one side surface of the semiconductor layer SPL.

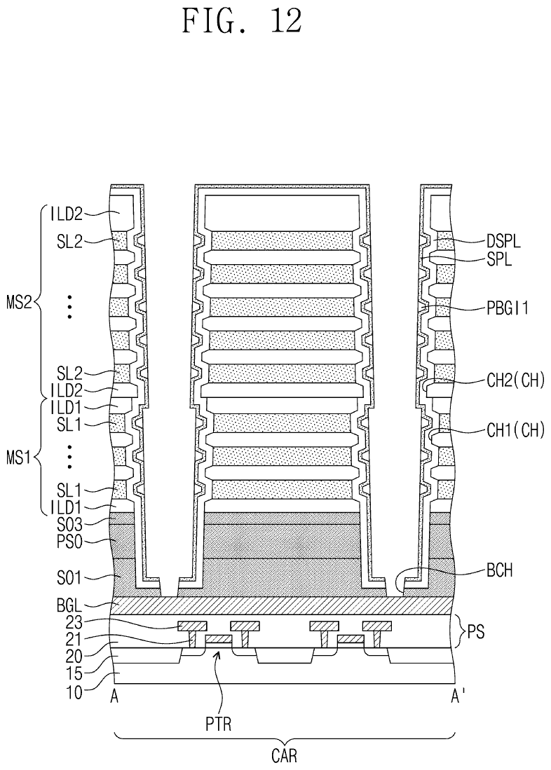

Referring to FIGS. 5 and 12, a first preliminary back-gate insulating pattern PBGI1 may be formed so as to fill the gapfill region GPR described with reference to FIG. 11. Thereafter, a process of partially removing the semiconductor layer SPL, the data storage layer DSPL and the first source layer SO1 may be performed, and a back-gate contact hole BCH may be formed. An upper surface of the back-gate line BGL may be partially exposed to the outside by the back-gate contact hole BCH.

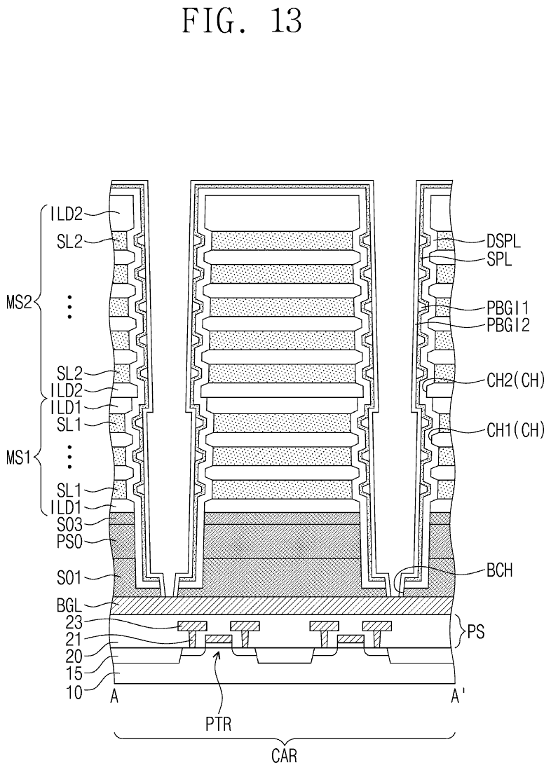

Referring to FIGS. 5 and 13, a second preliminary back-gate insulating pattern PBGI2 may be formed so as to conformally cover a side surface of each of the semiconductor layer SPL and the first preliminary back-gate insulating pattern PBGI1. The second preliminary back-gate insulating pattern PBGI2 may be formed so as to conformally cover the back-gate contact hole BCH.

Referring to FIGS. 5 and 6, a third preliminary back-gate insulating pattern (not shown) may be formed inside the channel holes CH. The first preliminary back-gate insulating pattern PBGI1 (see FIG. 13), the second preliminary back-gate insulating pattern PBGI2 (see FIG. 13), and the third preliminary back-gate insulating pattern may constitute the back-gate insulating pattern BGI together. A channel pad layer (not shown) may be formed on the back-gate insulating pattern BGI.

A process of removing an upper portion of each of the data storage layer DSPL (see FIG. 13), the semiconductor layer SPL (see FIG. 13) and the channel pad layer may be performed. Accordingly, each of the components may be respectively separated into the data storage patterns DSP, the semiconductor patterns SP and the channel pads CHP.

A separation trench (not shown) may be formed so as to penetrate the third source layer SO3 and the first and second mold structures MS1 and MS2. The second source layer SO2 may be formed instead of the preliminary source layer PSO exposed by the separation trench. The first to third source layers SO1, SO2 and SO3 may constitute the source layer SO.

Thereafter, an isotropic etching process may be performed using the separation trench as a path, and the first sacrificial layers SL1 and the second sacrificial layers may be removed. First and second gate electrodes GE1 and GE2 may be formed in positions in which the first sacrificial layers SL1 and the second sacrificial layers SL2 are removed, and the stack structure ST may be formed therethrough. A separation pattern SS may be formed so as to fill the separation trench.

According to the inventive concept, since the indent region IDR (see FIG. 12) is formed, each of the data storage layer DSPL (see FIG. 13) and the semiconductor layer SPL (see FIG. 13) may extend having a wavy profile. The gapfill region GPR (see FIG. 12) may be formed on the semiconductor layer SPL (see FIG. 13) due to the profile, and the first preliminary back-gate insulating pattern PBGI1 (see FIG. 13) may fill the gapfill region GPR. The second preliminary back-gate insulating pattern PBGI2 (see FIG. 13) may be formed on the first preliminary back-gate insulating pattern PBGI1 (see FIG. 13), and the back-gate electrode BG may be formed in the channel hole CH. Due to the manufacturing method above, the equivalent oxide thicknesses (EOT) between the first and second gate electrodes GE1 and GE2 and the semiconductor pattern SP are maintained, and at the same time, the equivalent oxide thickness (EOT) between the back-gate electrode BG and the semiconductor pattern SP becomes greater. As a result, the inventive concept may have the effect (improving reliability of the three-dimensional semiconductor memory device) of the inventive concept described above with reference to FIGS. 9A and 9B.

The upper insulating layer UIL may be formed on the stack structure ST. The bit line contact BLC may be formed so as to penetrate the upper insulating layer UIL on an upper surface of the channel pad CHP. The bit line BL may be formed on the upper insulating layer UIL.

According to the inventive concept, a thickness of a first region of a back-gate insulating pattern may be greater than a thickness of a second region. Accordingly, a distance between a back-gate electrode and a first semiconductor region may be greater than a distance between the back-gate electrode and a second semiconductor region. As a result, when a verification voltage is smaller than a threshold voltage, an inversion region in the first semiconductor region formed by a back-gate voltage may be easily canceled out by the verification voltage. Accordingly, when the verification voltage is smaller than the threshold voltage, an off current may be reduced. In addition, when the verification voltage is greater than the threshold voltage, the inversion region in the second semiconductor region may be more easily formed by the back-gate voltage. Accordingly, when the verification voltage is greater than the threshold voltage, an on current may increase. Since the inventive concept has a feature above, during a reading operation, the off current may be reduced, and at the same time, the on current may increase. Accordingly, reliability of a three-dimensional semiconductor memory device may be improved.

The above description of embodiments of the inventive concept provides an example for description of the inventive concept. Therefore, the inventive concept is not limited to the above embodiments, and it is obvious that various modifications and changes such as combining the above embodiments may be made by those skilled in the art within the technical spirit of the inventive concept.

What is claimed is:

1. A three-dimensional semiconductor memory device comprising:
a stack structure disposed on a substrate, the stack structure including gate electrodes and interlayered insulating layers alternately stacked along a first direction vertical to an upper surface of the substrate;
a semiconductor pattern penetrating the stack structure, and extending along the first direction;
a back-gate electrode extending on a side surface of the semiconductor pattern along the first direction; and
a back-gate insulating pattern between the semiconductor pattern and the back-gate electrode,
wherein the back-gate insulating pattern includes first regions between each of the gate electrodes and the back-gate electrode, and second regions between each of the interlayered insulating layers and the back-gate electrode, and
in a second direction parallel to the upper surface of the substrate, a thickness of each of the first regions of the back-gate insulating pattern is greater than a thickness of each of the second regions of the back-gate insulating pattern.

2. The three-dimensional semiconductor memory device of claim 1, wherein the back-gate insulating pattern has a first side surface adjacent to the semiconductor pattern, and a second side surface adjacent to the back-gate electrode, and
the first side surface of the back-gate insulating pattern has a wavy profile along the first direction.

3. The three-dimensional semiconductor memory device of claim 2, wherein the second side surface of the back-gate insulating pattern follows a profile of a side surface of the back-gate electrode.

4. The three-dimensional semiconductor memory device of claim 1, wherein one side surface of each of the first regions of the back-gate insulating pattern protrudes, in the second direction parallel to an upper surface of the substrate, more than one side surface of each of the second regions of the back-gate insulating pattern.

5. The three-dimensional semiconductor memory device of claim 1, wherein the semiconductor pattern comprises first semiconductor regions between the first regions of the back-gate insulating pattern and the gate electrodes, and second semiconductor regions between the second regions of the back-gate insulating pattern and the interlayered insulating layers, and
a distance between the back-gate electrode and the first semiconductor regions of the semiconductor pattern is greater than a distance between the back-gate electrode and the second semiconductor regions of the semiconductor pattern.

6. The three-dimensional semiconductor memory device of claim 1, wherein the semiconductor pattern comprises first semiconductor regions between the first regions of the back-gate insulating pattern and the gate electrodes, and second semiconductor regions between the second regions of the back-gate insulating pattern and the interlayered insulating layers, and
the first semiconductor regions of the semiconductor pattern protrude in the second direction parallel to an upper surface of the substrate more than the second semiconductor regions of the semiconductor pattern.

7. The three-dimensional semiconductor memory device of claim 1, wherein the semiconductor pattern has a wavy profile along the first direction.

8. The three-dimensional semiconductor memory device of claim 1, wherein the first regions and the second regions of the back-gate insulating pattern are alternately disposed along the first direction.

9. The three-dimensional semiconductor memory device of claim 1, wherein side surfaces of each of the interlayered insulating layers protrude, in the second direction parallel to an upper surface of the substrate, more than side surfaces of each of the gate electrodes.

10. The three-dimensional semiconductor memory device of claim 1, further comprising a data storage pattern between the gate electrodes and the semiconductor pattern,
wherein the data storage pattern has a wavy profile along the first direction.

11. The three-dimensional semiconductor memory device of claim 10, wherein the data storage pattern is disposed between the interlayered insulating layers.

12. A three-dimensional semiconductor memory device comprising:
a stack structure disposed on a substrate, the stack structure including gate electrodes and interlayered insulating layers alternately stacked along a first direction vertical to an upper surface of the substrate;
a semiconductor pattern penetrating the stack structure, and extending along the first direction;
a back-gate electrode extending on a side surface of the semiconductor pattern along the first direction; and
a back-gate insulating pattern between the semiconductor pattern and the back-gate electrode,
wherein the back-gate insulating pattern has a first side surface adjacent to the semiconductor pattern, and a second side surface adjacent to the back-gate electrode, and
the first side surface has a wavy profile along the first direction.

13. The three-dimensional semiconductor memory device of claim 12, wherein the second side surface follows a profile of a side surface of the back-gate electrode.

14. The three-dimensional semiconductor memory device of claim 12, wherein the semiconductor pattern has a wavy profile along the first direction.

15. The three-dimensional semiconductor memory device of claim 12, wherein the first side surface of the back-gate insulating pattern comprises a first surface and a second surface facing a second direction parallel to the upper surface of the substrate, and
the first surface of the first side surface of the back-gate insulating pattern protrudes, in the second direction parallel to the upper surface of the substrate, more than the second surface of the first side surface of the back-gate insulating pattern.

16. The three-dimensional semiconductor memory device of claim 15, wherein a distance between the back-gate electrode and the first surface of the first side surface of the back-gate insulating pattern is greater than a distance between the back-gate electrode and the second surface of the first side surface of the back-gate insulating pattern.

17. The three-dimensional semiconductor memory device of claim 15, wherein the semiconductor pattern comprises a first semiconductor region adjacent to the first surface of the first side surface of the back-gate insulating pattern and a second semiconductor region adjacent to the second surface of the first side surface, and
a distance between the back-gate electrode and the first semiconductor region is greater than a distance between the back-gate electrode and the second semiconductor region.

18. The three-dimensional semiconductor memory device of claim 12, wherein side surfaces of each of the interlayered insulating layers protrude, in a second direction parallel to the upper surface of the substrate, more than side surfaces of each of the gate electrodes.

19. The three-dimensional semiconductor memory device of claim 12, further comprising a data storage pattern extending between the gate electrodes and the semiconductor pattern along the first direction,
wherein the data storage pattern has a wavy profile along the first direction.

20. An electronic system comprising:
a three-dimensional semiconductor memory device; and
a controller electrically connected to the three-dimensional semiconductor memory device through an input/output pad, and configured to control the three-dimensional semiconductor memory device,
wherein the three-dimensional semiconductor memory device includes:
a stack structure disposed on a substrate, the stack structure including gate electrodes and interlayered insulating layers alternately stacked along a first direction vertical to an upper surface of the substrate;
a semiconductor pattern penetrating the stack structure, and extending along the first direction;
a back-gate electrode extending on a side surface of the semiconductor pattern along the first direction; and
a back-gate insulating pattern between the semiconductor pattern and the back-gate electrode,
the back-gate insulating pattern includes first regions between each of the gate electrodes and the back-gate electrode, and second regions between each of the interlayered insulating layers and the back-gate electrode, and
in a second direction parallel to the upper surface of the substrate, a thickness of each of the first regions of the back-gate insulating pattern is greater than a thickness of each of the second regions of the back-gate insulating pattern.
